(19) United States
(12) Patent Application Publication
(10) Pub. No.: US 2025/0103964 A1
(43) Pub. Date: Mar. 27, 2025

(54) TRAINING A MODEL TO GENERATE PREDICTIVE DATA

(71) Applicant: ASML Netherlands B.V., Veldhoven (NL)

(72) Inventors: Maxim PISARENCO, Son en Breugel (NL); Chrysostomos BATISTAKIS, Eindhoven (NL)

(73) Assignee: ASML Netherlands B.V., Veldhoven (NL)

(21) Appl. No.: 18/971,818

(22) Filed: Dec. 6, 2024

Related U.S. Application Data
(63) Continuation of application No. PCT/EP2023/069587, filed on Jul. 13, 2023.

(30) Foreign Application Priority Data
Jul. 25, 2022 (EP) 22186636.1
Sep. 19, 2022 (EP) 22196424.0

(51) Int. Cl. G06N 20/00

(52) U.S. Cl. CPC G06N 20/00

(57) ABSTRACT

A method of training a generator model comprising: using the generator model to generate the predictive data based on the first measured data, wherein the first measured data and the predictive data can be used to form images of the sample; pairing subsets of the first measured data with subsets of the predictive data, the subsets corresponding to locations within the images of the sample that can be formed from the first measured data and the predictive data; using a discriminator to evaluate a likelihood that the predictive data comes from a same data distribution as second measured data measured from a sample after an etching process; and training the generator model based on: correlation for the pairs corresponding to a same location relative to correlation for pairs corresponding to different locations, the correlation being the correlation between the paired subsets of data, and the likelihood evaluated by the discriminator.

### CROSS-REFERENCE TO RELATED APPLICATIONS

This application claims priority of International application PCT/EP2023/069587, filed on Jul. 13, 2023, which claims priority of EP application Ser. No. 22/186,636.1, filed on Jul. 25, 2022, and of EP application 22196424.0, filed on Sep. 19, 2022. These applications are incorporated herein by reference in their entireties.

### TECHNICAL FIELD

The embodiments disclosed herein relate to generating predictive data of a sample after an etching process based on measured data of the sample after an exposure process but before the etching process, for example to allow parameters of the sample to be optimized before etching.

### BACKGROUND

When manufacturing semiconductor integrated circuit (IC) chips, undesired pattern defects, as a consequence of, for example, optical effects and incidental particles, inevitably occur on a substrate (i.e. wafer) or a mask during the fabrication processes, thereby reducing the yield. Monitoring the extent of the undesired pattern defects is therefore an important process in the manufacture of IC chips. More generally, the inspection and/or measurement of a surface of a substrate, or other object/material, is an important process during and/or after its manufacture.

Pattern inspection apparatuses with a charged particle beam have been used to inspect objects, which may be referred to as samples, for example to detect pattern defects. These apparatuses typically use electron microscopy techniques, such as a scanning electron microscope (SEM). In a SEM, a primary electron beam of electrons at a relatively high energy is targeted with a final deceleration step in order to land on a sample at a relatively low landing energy. The beam of electrons is focused as a probing spot on the sample. The interactions between the material structure at the probing spot and the landing electrons from the beam of electrons cause signal electrons to be emitted from the surface, such as secondary electrons, backscattered electrons or Auger electrons. The signal electrons may be emitted from the material structure of the sample. By scanning the primary electron beam as the probing spot over the sample surface, signal electrons can be emitted across the surface of the sample. By collecting these emitted signal electrons from the sample surface, a pattern inspection apparatus may obtain an image representing characteristics of the material structure of the surface of the sample.

It may be desirable to scan the sample at different processing stages of the sample. For example, the sample may be scanned after a lithographic exposure process has been performed on it but before a subsequent etching process. This allows so-called after development inspection (ADI) images, sometimes known as after lithography inspection images, of the sample to be measured. The sample may subsequently be scanned after the etching process. This allows so-called after etching inspection (AEI) images of the sample to be formed. The data for these images may be used, for example to optimize parameters of the sample before etching and/or to improve lithographic processing for subsequent substrates. The process of scanning the sample can damage the sample, for example by damaging a resist material of the sample. The process of scanning can also reduce throughput of sample assessment methods.

There is a general need to improve throughput of sample assessment methods and/or reduce damage caused by sample assessment methods and/or improve accuracy.

### BRIEF SUMMARY

It is an object of the present disclosure to provide embodiments that support improved throughput in sample assessment methods and/or reduced damage caused by sample assessment methods.

According to some embodiments of the present disclosure, there is provided a method of training a generator model that processes first measured data measured from a sample before an etching process to generate predictive data predicting the sample after an etching process, the method comprising: using the generator model to generate the predictive data based on the first measured data, wherein the first measured data and the predictive data can be used to form images of the sample; pairing subsets of the first measured data with subsets of the predictive data, the subsets corresponding to locations within the images of the sample that can be formed from the measured data and the predictive data; using a discriminator to evaluate a likelihood that the predictive data comes from a same data distribution as second measured data measured from a sample at a different location after an etching process; and training the generator model based on: correlation for the pairs corresponding to a same location relative to correlation for pairs corresponding to different locations, the correlation being the correlation between the paired subsets of data, and the likelihood evaluated by the discriminator.

According to some embodiments of the present disclosure, there is provided a generator model training apparatus for training a generator model that processes first measured data measured from a sample before an etching process to generate predictive data predicting the sample after an etching process, the apparatus comprising: a processor configured to: use the generator model to generate the predictive data based on the first measured data, wherein the first measured data and the predictive data can be used to form images of the sample; pair subsets of the first measured data with subsets of the predictive data, the subsets corresponding to locations within the images of the sample that can be formed from the first measured data and the predictive data; use a discriminator to evaluate a likelihood that the predictive data comes from a same data distribution as second measured data measured from a sample at a different location after an etching process; and train the generator model based on: correlation for the pairs corresponding to a same location relative to correlation for pairs corresponding to different locations, the correlation being the correlation between the paired subsets of data, and the likelihood evaluated by the discriminator.

According to some embodiments of the present disclosure, there is provided a computer readable medium storing instructions configured to control a processor to train a generator model that processes first measured data measured from a sample before an etching process to generate predictive data predicting the sample after an etching process, the computer readable medium storing instructions configured to control the processor to: use the generator model to generate the predictive data based on the first measured data, wherein the first measured data and the predictive data can be used to form images of the sample; pair subsets of the first measured data with subsets of the predictive data, the subsets corresponding to locations within the images of the sample that can be formed from the measured data and the predictive data; use a discriminator to evaluate a likelihood that the predictive data comes from a same data distribution as second measured data measured from a sample at a different location after an etching process; and train the generator model based on: correlation for the pairs corresponding to a same location relative to correlation for pairs corresponding to different locations, the correlation being the correlation between the paired subsets of data, and the likelihood evaluated by the discriminator.

According to some embodiments of the present disclosure, there is provided a method of training a generator model that processes paired measured data measured from a sample after an etching process, the sample having previously been measured before the etching process, to generate hypothetical data simulating the sample after the etching process if the sample had not previously been measured before the etching process, the method comprising: using the generator model to generate the hypothetical data based on the paired measured data, wherein the paired measured data and the hypothetical data can be used to form images of the sample; using a discriminator to evaluate a likelihood that the hypothetical data comes from a same data distribution as real measured data measured from a sample after an etching process, the sample not having previously been measured before the etching process; and training the generator model based on: a function indicative of a level of correlation between the paired measured data and the hypothetical data, and the likelihood evaluated by the discriminator.

According to some embodiments of the present disclosure, there is provided a generator model training apparatus for training a generator model that processes paired measured data measured from a sample after an etching process, the sample having previously been measured before the etching process, to generate hypothetical data simulating the sample after the etching process if the sample had not previously been measured before the etching process, the apparatus comprising: a processor configured to: use the generator model to generate the hypothetical data based on the paired measured data, wherein the paired measured data and the hypothetical data can be used to form images of the sample; use a discriminator to evaluate a likelihood that the hypothetical data comes from a same data distribution as real measured data measured from a sample after an etching process, the sample not having previously been measured before the etching process; and train the generator model based on: a function indicative of a level of correlation between the paired measured data and the hypothetical data, and the likelihood evaluated by the discriminator.

According to some embodiments of the present disclosure, there is provided a computer readable medium storing instructions configured to control a processor to train a generator model that processes paired measured data measured from a sample after an etching process, the sample having previously been measured before the etching process, to generate hypothetical data simulating the sample after the etching process if the sample had not previously been measured before the etching process, the computer readable medium storing instructions configured to control the processor to: use the generator model to generate the hypothetical data based on the paired measured data, wherein the paired measured data and the hypothetical data can be used to form images of the sample; use a discriminator to evaluate a likelihood that the hypothetical data comes from a same data distribution as real measured data measured from a sample after an etching process, the sample not having previously been measured before the etching process; and train the generator model based on: a function indicative of a level of correlation between the paired measured data and the hypothetical data, and the likelihood evaluated by the discriminator.

### BRIEF DESCRIPTION OF FIGURES

The above and other aspects of the present disclosure will become more apparent from the description of exemplary embodiments, taken in conjunction with the accompanying drawings.

FIG. 1 is a schematic diagram illustrating an exemplary charged particle beam inspection system.

FIG. 2 is a schematic diagram illustrating an exemplary multi-beam charged particle assessment apparatus that is part of the exemplary charged particle beam inspection system of FIG. 1.

FIG. 3 is a schematic diagram of an exemplary single beam electron optical column.

FIG. 4 depicts images of a sample before and after an etching process taken at different locations on the sample.

FIG. 5 depicts patches of an image of the sample before the etching process paired with a patch of a predicted image of the same sample after the etching process.

The schematic diagrams and views show the components described below. However, the components depicted in the figures are not to scale.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims and clauses.

The enhanced computing power of electronic devices, which reduces the physical size of the devices, can be accomplished by significantly increasing the packing density of circuit components such as transistors, capacitors, diodes, etc. on an IC chip. This has been enabled by increased resolution enabling yet smaller structures to be made. For example, an IC chip of a smart phone, which is the size of a thumbnail and available in, or earlier than, 2019, may include over 2 billion transistors, the size of each transistor being less than 1/1000th of a human hair. Thus, it is not surprising that semiconductor IC manufacturing is a complex and time-consuming process, with hundreds of individual steps. Errors in even one step have the potential to dramatically affect the functioning of the final product. Just one “killer defect” can cause device failure. The goal of the manufacturing process is to improve the overall yield of the process. For example, to obtain a 75% yield for a 50-step process (where a step can indicate the number of layers formed on a wafer), each individual step must have a yield greater than 99.4%. If each individual step had a yield of 95%, the overall process yield would be as low as 7%.

While high process yield is desirable in an IC chip manufacturing facility, maintaining a high substrate (i.e. wafer) throughput, defined as the number of substrates processed per hour, is also essential. High process yield and high substrate throughput can be impacted by the presence of a defect. This is especially true if operator intervention is required for reviewing the defects. Thus, high throughput detection and identification of micro and nano-scale defects by inspection devices (such as a Scanning Electron Microscope (SEM)) is essential for maintaining high yield and low cost.

A SEM comprises a scanning device and a detector apparatus. The scanning device comprises an illumination apparatus that comprises an electron source, for generating primary electrons, and a projection apparatus for scanning a sample, such as a substrate, with one or more focused beams of primary electrons. Together at least the illumination apparatus, or illumination system, and the projection apparatus, or projection system, may be referred to together as the electron-optical system or apparatus. The primary electrons interact with the sample and generate secondary electrons. The detection apparatus captures the secondary electrons from the sample as the sample is scanned so that the SEM can create an image of the scanned area of the sample. For high throughput inspection, some of the inspection apparatuses use multiple focused beams, i.e. a multi-beam, of primary electrons. The component beams of the multi-beam may be referred to as sub-beams or beamlets. A multi-beam can scan different parts of a sample simultaneously. A multi-beam inspection apparatus can therefore inspect a sample at a much higher speed than a single-beam inspection apparatus.

An implementation of a known multi-beam inspection apparatus is described below.

While the description and drawings are directed to an electron-optical system, it is appreciated that the embodiments are not used to limit the present disclosure to specific charged particles. References to electrons throughout the present document may therefore be more generally considered to be references to charged particles, with the charged particles not necessarily being electrons.

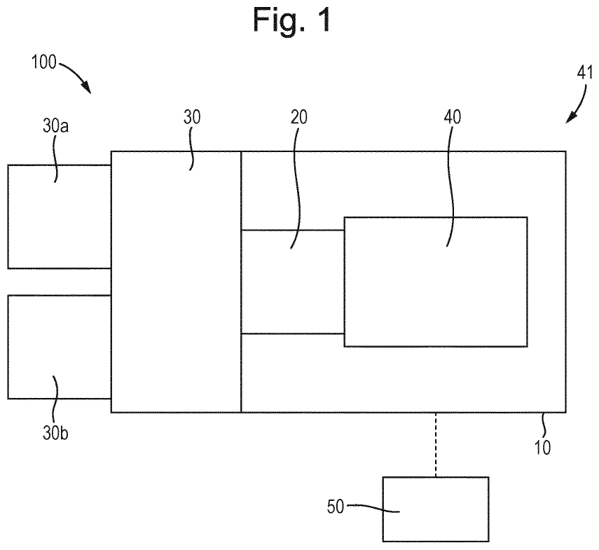

Reference is now made to FIG. 1, which is a schematic diagram illustrating an exemplary charged particle beam inspection system 100, which may also be referred to as a charged particle beam assessment system or simply assessment system. The charged particle beam inspection system 100 of FIG. 1 includes a main chamber 10, a load lock chamber 20, an electron beam system 40, an equipment front end module (EFEM) 30 and a controller 50. The electron beam system 40 is located within the main chamber 10.

The EFEM 30 includes a first loading port 30a and a second loading port 30b. The EFEM 30 may include additional loading port(s). The first loading port 30a and the second loading port 30b may, for example, receive substrate front opening unified pods (FOUPs) that contain substrates (e.g., semiconductor substrates or substrates made of other material(s)) or samples to be inspected (substrates, wafers and samples are collectively referred to as “samples” hereafter). One or more robot arms (not shown) in the EFEM 30 transport the samples to the load lock chamber 20.

The load lock chamber 20 is used to remove the gas around a sample. This creates a vacuum that is a local gas pressure lower than the pressure in the surrounding environment. The load lock chamber 20 may be connected to a load lock vacuum pump system (not shown), which removes gas particles in the load lock chamber 20. The operation of the load lock vacuum pump system enables the load lock chamber to reach a first pressure below the atmospheric pressure. After reaching the first pressure, one or more robot arms (not shown) transport the sample from the load lock chamber 20 to the main chamber 10. The main chamber 10 is connected to a main chamber vacuum pump system (not shown). The main chamber vacuum pump system removes gas particles in the main chamber 10 so that the pressure in around the sample reaches a second pressure lower than the first pressure. After reaching the second pressure, the sample is transported to the electron beam system by which it may be inspected. An electron beam system 40 may comprise a multi-beam electron-optical apparatus.

The controller 50 is electronically connected to electron beam system 40. The controller 50 may be a processor (such as a computer) configured to control the charged particle beam inspection apparatus 100. The controller 50 may also include a processing circuitry configured to execute various signal and image processing functions. While the controller 50 is shown in FIG. 1 as being outside of the structure that includes the main chamber 10, the load lock chamber 20, and the EFEM 30, it is appreciated that the controller 50 may be part of the structure. The controller 50 may be located in one of the component elements of the charged particle beam inspection apparatus or it can be distributed over at least two of the component elements. While the present disclosure provides examples of the main chamber 10 housing an electron beam system, it should be noted that aspects of the disclosure in their broadest sense are not limited to a chamber housing an electron beam system. Rather, it is appreciated that the foregoing principles may also be applied to other devices, and other arrangements of apparatus, that operate under the second pressure.

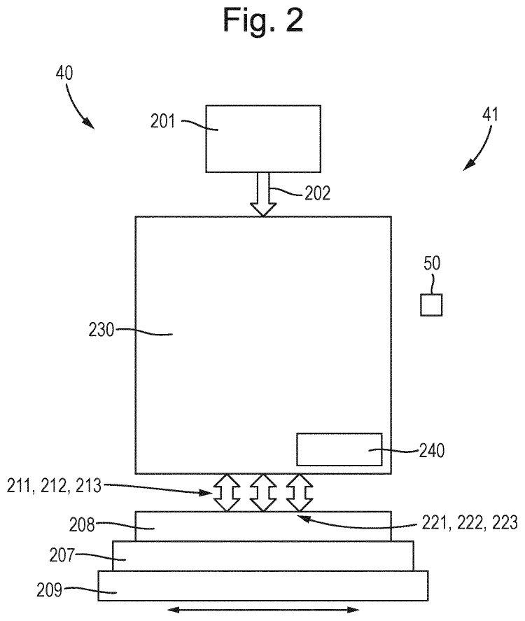

Reference is now made to FIG. 2, which is a schematic diagram illustrating an exemplary electron beam system 40, including a multi-beam electron-optical system 41, that is part of the exemplary charged particle beam inspection system 100 of FIG. 1. The electron beam system 40 comprises an electron source 201 and a projection apparatus 230. The electron beam system 40 further comprises a motorized stage 209 and a sample holder 207. The electron source 201 and projection apparatus 230 may together be referred to as the electron-optical system 41 or as an electron-optical column. The sample holder 207 is supported by motorized stage 209 so as to hold a sample 208 (e.g., a substrate or a mask) for inspection. The multi-beam electron-optical system 41 further comprises a detector 240 (e.g. an electron detection device).

The electron source 201 may comprise a cathode (not shown) and an extractor or anode (not shown). During operation, the electron source 201 is configured to emit electrons as primary electrons from the cathode. The primary electrons are extracted or accelerated by the extractor and/or the anode to form a primary electron beam 202.

The projection apparatus 230 is configured to convert the primary electron beam 202 into a plurality of sub-beams 211, 212, 213 and to direct each sub-beam onto the sample 208. Although three sub-beams are illustrated for simplicity, there may be many tens, many hundreds, many thousands, many tens of thousands or many hundreds of thousands of sub-beams. The sub-beams may be referred to as beamlets.

The controller 50 may be connected to various parts of the charged particle beam inspection apparatus 100 of FIG. 1, such as the electron source 201, the detector 240, the projection apparatus 230, and the motorized stage 209. The controller 50 may perform various image and signal processing functions. The controller 50 may also generate various control signals to govern operations of the charged particle beam inspection apparatus, including the charged particle multi-beam apparatus.

The projection apparatus 230 may be configured to focus sub-beams 211, 212, and 213 onto a sample 208 for inspection and may form three probe spots 221, 222, and 223 on the surface of sample 208. The projection apparatus 230 may be configured to deflect the primary sub-beams 211, 212, and 213 to scan the probe spots 221, 222, and 223 across individual scanning areas in a section of the surface of the sample 208. In response to incidence of the primary sub-beams 211, 212, and 213 on the probe spots 221, 222, and 223 on the sample 208, electrons are generated from the sample 208 which include secondary electrons and backscattered electrons which may be referred to as signal particles. The secondary electrons typically have electron energy less than or equal to 50 eV. Actual secondary electrons can have an energy of less than 5 eV, but anything beneath 50 eV is generally treated at a secondary electron. Backscattered electrons typically have electron energy between 0 eV and the landing energy of the primary sub-beams 211, 212, and 213. As electrons detected with an energy of less than 50 eV is generally treated as a secondary electron, a proportion of the actual backscatter electrons will be counted as secondary electrons.

The detector 240 is configured to detect signal particles such as secondary electrons and/or backscattered electrons and to generate corresponding signals which are sent to a signal processing system 280, e.g. to construct images of the corresponding scanned areas of sample 208. The detector 240 may be incorporated into the projection apparatus 230.

The signal processing system 280 may comprise a circuit (not shown) configured to process signals from the detector 240 so as to form an image. The signal processing system 280 could otherwise be referred to as an image processing system. The signal processing system may be incorporated into a component of the electron beam system 40 such as the detector 240 (as shown in FIG. 2). However, the signal processing system 280 may be incorporated into any number of components of the inspection apparatus 100 or electron beam system 40, such as, as part of the projection apparatus 230 or the controller 50. The signal processing system 280 may include an image acquirer (not shown) and a storage device (not shown). For example, the signal processing system may comprise a processor, computer, server, mainframe host, terminals, personal computer, any kind of mobile computing devices, and the like, or a combination thereof. The image acquirer may comprise at least part of the processing function of the controller. Thus the image acquirer may comprise at least one or more processors. The image acquirer may be communicatively coupled to the detector 240 permitting signal communication. such as an electrical conductor, optical fiber cable, portable storage media, IR, Bluetooth, internet, wireless network, wireless radio, among others, or a combination thereof. The image acquirer may receive a signal from the detector 240, may process the data comprised in the signal and may construct an image therefrom. The image acquirer may thus acquire images of the sample 208. The image acquirer may also perform various post-processing functions, such as generating contours, superimposing indicators on an acquired image, and the like. The image acquirer may be configured to perform adjustments of brightness and contrast, etc. of acquired images. The storage may be a storage medium such as a hard disk, flash drive, cloud storage, random access memory (RAM), other types of computer readable memory, and the like. The storage may be coupled with the image acquirer and may be used for saving scanned raw image data as original images, and post-processed images.

The signal processing system 280 may include measurement circuitry (e.g., analog-to-digital converters) to obtain a distribution of the detected secondary electrons. The electron distribution data, collected during a detection time window, can be used in combination with corresponding scan path data of each of primary sub-beams 211, 212, and 213 incident on the sample surface, to reconstruct images of the sample structures under inspection. The reconstructed images can be used to reveal various features of the internal or external structures of the sample 208. The reconstructed images can thereby be used to reveal any defects that may exist in the sample. The above functions of the signal processing system 280 may be carried out in the controller 50 or shared between the signal processing systems 280 and controller 50 as convenient.

The controller 50 may control the motorized stage 209 to move sample 208 during inspection of the sample 208. The controller 50 may enable the motorized stage 209 to move the sample 208 in a direction, preferably continuously, for example at a constant speed, at least during sample inspection, which may be referred to as a type of scanning. The controller 50 may control movement of the motorized stage 209 so that it changes the speed of the movement of the sample 208 depending on various parameters. For example, the controller 50 may control the stage speed (including its direction) depending on the characteristics of the inspection steps of scanning process and/or scans of the scanning process for example as disclosed in EPA 21171877.0 filed 3 May 2021 which is hereby incorporated in so far as the combined stepping and scanning strategy at least of the stage.

Known multi-beam systems, such as the electron beam system 40 and charged particle beam inspection apparatus 100 described above, are disclosed in US2020118784, US20200203116, US 2019/0259570 and US2019/0259564 which are hereby incorporated by reference.

The electron beam system 40 may comprise a projection assembly to regulate accumulated charges on the sample by illuminating the sample 208.

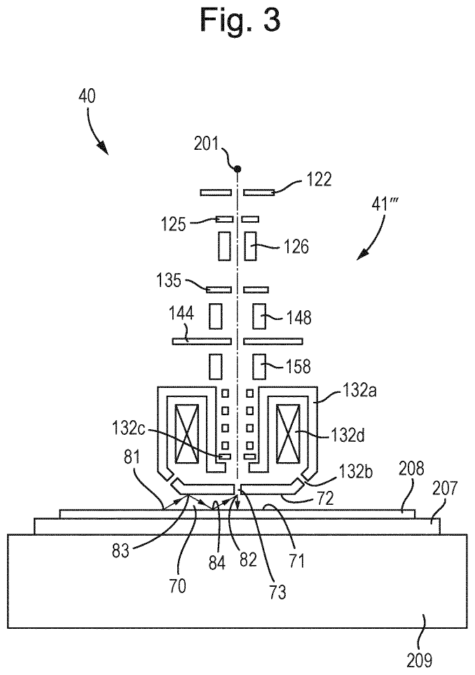

FIG. 3 is a schematic diagram of an exemplary single beam electron beam system 41′″ according to some embodiments. As shown in FIG. 3, in some embodiments, the electron beam system comprises a sample holder 207 supported by a motorized stage 209 to hold a sample 208 to be inspected. The electron beam system comprises an electron source 201. The electron beam system further comprises a gun aperture 122, a beam limit aperture 125, a condenser lens 126, a column aperture 135, an objective lens assembly 132, and an electron detector 144. The objective lens assembly 132, in some embodiments, may be a modified swing objective retarding immersion lens (SORIL), which includes a pole piece 132a, a control electrode 132b, a deflector 132c, and an exciting coil 132d. The control electrode 132b has an aperture formed in it for the passage of the electron beam. The control electrode 132b forms the facing surface 72, described in more detail below.

In an imaging process, an electron beam emanating from the source 201 may pass through the gun aperture 122, the beam limit aperture 125, the condenser lens 126, and be focused into a probe spot by the modified SORIL lens and then impinge onto the surface of sample 208. The probe spot may be scanned across the surface of the sample 208 by the deflector 132c or other deflectors in the SORIL lens. Secondary electrons emanated from the sample surface may be collected by the electron detector 144 to form an image of an area of interest on the sample 208.

The condenser and illumination optics of the electron-optical system 41 may comprise or be supplemented by electromagnetic quadrupole electron lenses. For example, as shown in FIG. 3 the electron-optical system 41 may comprise a first quadrupole lens 148 and a second quadrupole lens 158. In some embodiments, the quadrupole lenses are used for controlling the electron beam. For example, first quadrupole lens 148 can be controlled to adjust the beam current and second quadrupole lens 158 can be controlled to adjust the beam spot size and beam shape.

As mentioned in the introductory part of the description, sample assessment methods may be used to assess the extent of undesired patent defects in a sample. Such methods may involve scanning the sample (or at least a portion of the sample) at one or more stages of the process of forming the pattern. When manufacturing IC chips, the fabrication process may involve a lithographie exposure process. The lithographic exposure process may comprise irradiating a sample (i.e. a substrate) with radiation. For example, a resist (e.g. a photoresist) may be irradiated. The fabrication process may comprise an etching process. The etching process may comprise etching irradiated or non-irradiated portions of the resist.

The sample may be scanned after the exposure process and before the etching process, so called after development inspection (ADI). This scanning may produce information about the extent of undesired patent defects in the sample. This information may be used to form images of the sample. It may not be necessary to form the images. For example, the information (from which the images can be formed) may be used in a subsequent processing step without the images actually being produced. The data sets formed by scanning the sample after the exposure process and before the etching process may be referred to as ADI images. Additionally or alternatively, the sample may be scanned after the etching process (and therefore also after the exposure process), so called after etch inspection (AEI). This may produce data about the extent of undesired patent defects in the sample. The data can be used to form images. The data may be referred to as AEI images. It may not be necessary to produce the visual images. Instead, the data that can be used to form the images may be used in a subsequent processing step without actually producing the images.

There is disclosed a method of training a generator model. The generator model is configured to process first measured data 60 to generate predictive data 81. The first measured data 60 is measured from a sample 208 before an etching process. The etching process is a process of etching the sample 208, for example etching a layer of resist of the sample 208. In some embodiments, the first measured data comprises data that can be used to form ADI images. The predictive data 81 predicts the sample 208 after an etching process. The predictive data 81 may be data that can be used to form AEI images.

In some embodiments, the method is for training a deep learning model (i.e. the generator model) that can map between ADI and AEI SEM images. In some embodiments, the method comprises measuring the first measured data 60 from the sample 208. For example, the first measured data 60 may be measured from the sample 208 by scanning the sample 208 with a charged particle beam inspection system 100 (e.g. an SEM). Alternatively, the first measured data 60 may have already been measured from the sample 208. The method may use the first measured data 60 that has already been measured from the sample 208.

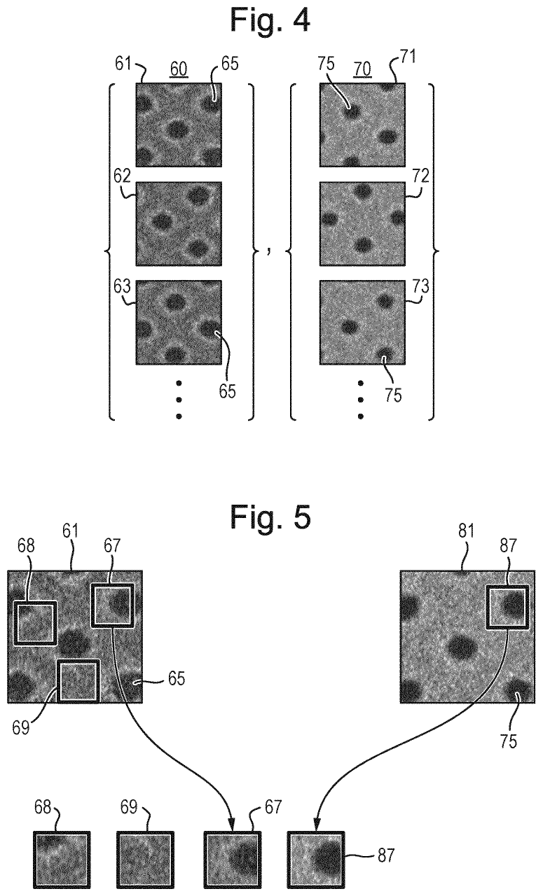

FIG. 4 is a diagram showing data sets used in a method according to some embodiments of the present disclosure. The data set shown in the left-hand side of FIG. 4 corresponds to the first measured data 60. As shown in FIG. 4 in some embodiments, the first measured data 60 comprises one or more ADI images 61-63. In the example shown in FIG. 4, the ADI images 61-63 show contact holes 65 of the sample 208. As shown in FIG. 4, the contact holes 65 may have a generally round shape when viewed in a top-down view. The sample 208 may have additional or alternative features. For example, the sample 208 may have linear features.

In some embodiments, the method comprises using the generator module to generate the predictive data 81 based on the first measured data 60. The first measured data 60 and the predictive data 81 can be used to form images of the sample 208.

FIG. 5 is a diagram showing an ADI image 61 of the first measured data 60 and a predictive AEI image that can be formed from the predictive data 81. Referring to FIG. 5, in some embodiments, the method comprises pairing subsets 67-69 of the first measured data 60 with subsets 87 of the predictive data 81. As shown in FIG. 5, the subsets 67-69, 87 correspond to locations within the images of the sample 208 that can be formed from the first measured data 60 and the predictive data 81.

From the subsets 67-69, 87 of data shown in FIG. 5, three possible pairs can be made. A first pair may be formed between the subset 67 and the subset 87. These two subsets 67, 87 correspond to the same location of the sample 208, as shown from a comparison between the ADI image 61 and the AEI image formed from the predictive data 81 shown in FIG. 5. In contrast, the subsets 68, 69 correspond to a different locations from the subset 87. A second possible pair can be formed with the subset 68 and the subset 87. The third possible pair can be formed between the subset 69 and the subset 87. Each pair consists of a subset of the first measured data 60 and a subset of the predictive data 81. Some pairs such as the first pair of subsets 67, 87 correspond to the same location of the sample 208. Other pairs such as the second pair and the third pair mentioned above correspond to different locations of the sample 208.

In some embodiments, the method comprises training the generator model based on correlation for the pairs corresponding to the same location relative to correlation for pairs corresponding to different locations. The correlation is the correlation between the two subsets of data of a pair. For example, in some embodiments, the method comprises determining the correlation between the subset 67 from the first measured data 60 and the subset 87 from the predictive data 81. The correlation may be determined by calculating the cross-entropy for the paired subsets of data. In some embodiments, the method comprises determining the correlation for other paired subsets of data that correspond to different locations, for example the second pair of subsets 68, 87 and the third pair of subsets 69, 87. The determination of the correlation may comprise determining the cross-entropy of each pair.

In some embodiments, the generator model is trained so as to increase correlation for the pairs corresponding to the same location relative to correlation for pairs corresponding to different locations. The generator model is trained so as to generally increase the similarity between the ADI image 61 from the first measured data 60 and the predictive AEI image formed from the predictive data 81. In practice, the sample 208 is altered during the etching process. There is therefore expected to be some difference between the ADI image 61 and the predictive AEI image formed from the predictive data 81. However, in general the measured ADI image 61 and the predictive AEI image are expected to show the same physical structures, for example, the same features (e.g. contact holes or linear features) of the sample 208.

As shown in FIG. 5, the contact holes 65 visible in the ADI image 61 may be similarly visible as after-etch contact holes 75 in the predictive AEI image. The parameters and dimensions of the features may be different between the two images. For example, the critical dimension (CD) may be different. However, the general shape of the physical structure may remain the same. By training the generator model based on correlation for the pairs corresponding to the same location relative to correlation for pairs corresponding to different locations the generator model may be expected to improve.

By generating the predictive data 81, it may not be necessary to scan the sample 208 so as to form an AEI image for the location corresponding to a measured ADI image 61-63. At least some embodiments of the present disclosure are expected to reduce damage to the sample 208. It is not necessary to measure ADI images and AEI images at the same locations of the sample 208. This is desirable because inspection of the sample 208 can otherwise damage the sample. For example, ADI can have a damaging effect on the resist, and this effect can impact what is measured after the etching process. At least some embodiments of the present disclosure are expected to improve the accuracy of forming a pattern on the sample 208.

The subsets 67-69, 87 of data may be referred to as patches. In some embodiments, the method comprises comparing patches from the ADI images 61 and generated AEI images. In some embodiments, the method comprises setting ADI patches corresponding to AEI patches as positive examples. For example, the first pair of subsets 67, 87 is considered as a positive example because the ADI patch 67 corresponds to the AEI patch 87 in that they correspond to the same location of the sample 208. In some embodiments, all other pairs of patches are set as negative examples. For example, the second pair of subsets 68,87 and the third pair of subsets 69.87 may be set as negative examples. In some embodiments, the method comprises reducing, or minimizing the cross-entropy for the positive examples.

In some embodiments, the method comprises using a discriminator to evaluate a likelihood that the predictive data 81 comes from the same data distribution as second measured data 70. The second measured data 70 is measured from a sample 208 after an etching process. The second measured data 70 is shown in the right-hand side of FIG. 4. The second measured data 70 may be used to form AEI images 71-73. The AEI images 71-73 show after-etching views of the contact holes 75. In some embodiments, the method comprises measuring the second measured data 70 from the sample 208. For example, the second measured data 70 may be measured by scanning the sample 208 after an etching process using a charged particle called beam inspection system 100 (e.g. an SEM). Alternatively, the second measured data 70 may have previously been measured.

In some embodiments, a generative adversarial network (GAN) is used. The discriminator is configured to assess how likely it is that the predictive AEI image formed from the predictive data 81 fits with the real AEI images 71-73 formed from the second measured data 70. In some embodiments, the method comprises training the generator model based on the likelihood evaluated by the discriminator. For example the generator model may be trained so as to increase the likelihood evaluated by the discriminator. By taking into account the assessment made by the discriminator, the generator model may be expected to improve.

In some embodiments, the output of the generator model is constrained to produce images (or sets of data that can be used to form images) that come from the same distribution as the AEI images 71-73 in the training set. The training set may comprise the ADI images 61-63 of the first measured data 60 and the AEI images 71-73 of the second measured data 70. In some embodiments, the discriminator network is used to take the predictive data 81 as an input and output a value, for example a value between 0 and 1. In some embodiments, the larger the value output by the discriminator, the more an image formed from the predictive data 81 looks like coming from the desired distribution, namely the AEI images 71-73 of the second measured data 70.

In some embodiments, the generator model is trained based on the calculated patch-wise contrastive loss and the discriminator. At least some embodiments of the present disclosure are expected to allow the generator model to be effective over a broader range of possible mappings between the ADI images and the AEI images. For example, it may be the case that the mapping between the first measured data 60 and the second measured data 70 is non-invertible. This means that there is not, for example, a one-to-one correspondence between an ADI image 61 from the first measured data 60 and a corresponding image of the same location of the sample 208 after the etching process. As one example, it may be that differently sized contact holes of the sample 208 before the etching process subsequently have the same dimension after the etching process. As a result, it is not possible to map back from an AEI image to determine what the dimension of the contact hole was before the etching process. This is an example of a non-invertible mapping. At least some embodiments of the present disclosure are expected to allow accurate predictive data to be generated without relying on the ADI/AEI mapping to be invertible.

In some embodiments, the method comprises calculating one or more parameter values for one or more parameters of features of the sample 208 from the predictive data 81 and from the second measured data 70. For example, in some embodiments, the parameters may comprise one more of CD, local critical dimension uniformity (LCDU), local edge placement error (LEPE), line edge roughness and line width roughness. LCDU relates to the uniformity of CD values for features such as contact holes or linear features. The CD values may be calculated locally and their standard deviation calculated so as to determine the LCDU. LEPE relates to the placement of the edges of features. The LEPE may be a combination of CD and overlay. Line edge roughness relates to the uniformity of the position of the edge of a line, for a linear feature. The line edge roughness may be a measure of how straight the edge of a linear feature is. Line width roughness relates to the uniformity of the width of a linear feature along its length. One or more key performance indicators such as these parameters may be taken into account when training the generator model.

In some embodiments, the method comprises comparing the one or more parameter values calculated from the predictive data 81 to the one or more parameter values calculated from the second measured data 70. In some embodiments, the evaluation by the discriminator is dependent on the comparison of the one or more parameter values. The discriminator may receive the parameter values in order to enforce a matching of the distributions of the parameters. For example, the discriminator may take into account the likelihood that the CD calculated from the predictive data 81 comes from the distribution of CD values calculated from the second measured data 70. At least some embodiments of the present disclosure are expected to improve the generator model applied to images of a sample 208 during lithographic processes.

In some embodiments, the likelihood evaluated by the discriminator is greater for a smaller difference between the one or more parameter values calculated from the predictive data 81 and the one or more parameter values calculated from the second measured data 70. Such a smaller difference may indicate that the predictive data 81 matches well with the second measured data 70. Greater differences may indicate that the predictive data 81 is less realistic.

At least some embodiments of the present disclosure are expected to reduce the requirement for the ADI/AEI mapping to be invertible. In practice, the ADI/AEI mapping is not likely to be perfectly invertible. At least some embodiments of the present disclosure are expected to enable a more accurate edge-bias prediction over a broader application space. At least some embodiments of the present disclosure are expected to improve the lithographic process.

In some embodiments, the generator model is trained by minimizing the following loss L:

$$L ( G , D , X , Y ) = {L}_{GAN} ( G , D , X , Y ) + α {L}_{patch} ( G , H , X )$$

The overall loss function L is a sum of two contributing losses, L_{GAN} and L_{patch}. L_{GAN} is related to how well the predictive AEI images fit in the same data distribution as the measured AEI images. L_{GAN} refers to the loss function corresponding to the evaluation by the discriminator. L_{patch} is related to the similarity between the measured ADI images and the predictive AEI images. L_{patch} is the loss function for the patch-wise contrastive loss. α is a parameter that can be controlled to control the extent to which the generator model is trained based on increasing similarity between the ADI images and AEI images and the extent to which the generator model is trained based on improving the similarity between the predictive AEI images and the measured AEI images. A greater value for α means a greater extent to which the generator model is trained based on increasing similarity between the measured ADI images and the predictive AEI images.

The loss functions are functions of G, D, X, Y and H. G refers to the generator model. D refers to the discriminator model. X refers to the first measured data 60. Y refers to the second measured data 70. H refers to a network that extract features from the first measured data 60 so as to compress the first measured data 60 into relevant features of the sample 208.

The contributing loss functions may be defined mathematically as follows:

$${L}_{GAN} ( G , {D}_{Y} ) = {E}_{x \sim {p}_{data} ( x )} [ log ( 1 - {D}_{Y} ( G ( x ) ) ) ] + {E}_{y \sim {p}_{data} ( y )} [ log {D}_{Y} ( y ) ]$$

$${L}_{patch} ( G , H , X ) = {E}_{x \sim {p}_{data} ( x )} {\sum }_{layers l} {\sum }_{layers s} crossentropy ( {z}_{l}^{s} , {z}_{l}^{s , +} , {z}_{l}^{s , -} )$$

$$where$$

$${z}_{l}^{s} = {H}_{l} ( {G}_{enc}^{l} ( G ( x ) ) )$$

$${z}_{l}^{s , + / -} = {H}_{l} ( {G}_{enc}^{l} ( x ) )$$

E refers to the expectation value over the data distributions. The z components relate to compressed representations of the patches, i.e. the subsets of data from the first measured data 60 and the predictive data 81.

In some embodiments, the generator model comprises an encoder and a decoder. As shown above, in some embodiments, the method comprises determining cross-entropy of extracted features of the paired subsets of data so as to determine the correlation between the paired subsets of data. In some embodiments, the method comprises encoding the paired subsets of data with the encoder of the generator model such that the features can be extracted.

As shown above, in some embodiments, the patch-wise contrastive loss is calculated by summing over a plurality of patches. In some embodiments, the patch-wise contrastive loss function is determined by summing over a plurality of layers of the sample 208. The sample 208 may comprise a plurality of layers. Each layer may comprise a set of features.

In some embodiments, there is provided a method of processing first measured data 60 measured from a sample 208 before an etching process to generate predictive data 81 predicting the sample 208 after an etching process. In some embodiments, the method comprises using a generator model to generate the predictive data 81 based on the first measured data 60. In some embodiments, the generator model has been trained by the method described above.

In some embodiments, the method comprises applying a deep learning model (i.e. the generator model) that can map between ADI and AEI SEM images. In some embodiments, a given ADI SEM image is converted to a corresponding predicted AEI SEM image. Alternatively, it may not be necessary to produce the images. In some embodiments, the method comprises converting given ADI data to corresponding predicted AEI data.

As described above it is possible to generate the predictive data without using measure-etch-measure (MEM) data. MEM data is data measured when both ADI and AEI are performed at the relevant location. In some embodiments, there is provided a method of applying correction on MEM data using unpaired image mapping.

As described above, patch-wise contrastive loss and a discriminator may be used. In some embodiments, these techniques or alternatively a cycleGAN technique may be used in combination with MEM data.

In some embodiments, there is a method of training a generator model that processes paired measured data measured from a sample after an etching process, the sample having previously been measured before the etching process, to generate hypothetical data simulating the sample after the etching process if the sample had not previously been measured before the etching process.

In some embodiments, the method comprises producing the paired measured data. In some

embodiments, the method comprises inspecting a portion of the sample after a development process and before any etching process (e.g. generating an ADI image). The inspection may be by electron beams. In some embodiments, the charged particle beam inspection system 100 is used to inspect the sample with one or more charged particle beams (e.g. electron beams). The method may further comprise inspecting the same portion of the sample after an etching process (e.g. generating an AEI image). The ADI image and the AEI image may correspond to the same location of the sample. The data measured after the etching process is the paired measured data.

During the process of inspecting the sample before the etching process, the sample may be damaged. In particular the electron beam(s) used to inspect the sample may damage the resist. The damage affects the paired measured data that is recorded after the etching process. The paired measured data is therefore different from what data would have been measured after etching if the sample had not been inspected before the etching process. Of course there may be some stochastic variation in measured data. Such stochastic variations may be accounted for by repeating measurements and taking averages. However, the damage to the sample caused by the inspection done after development and before etching is a difference that remains even when averaging over repeated measurements. Due to the resist damage caused by the ADI, the AEI pattern is affected and it is not fully realistic.

In some embodiments, the paired measured data has previously been generated. The method may be performed using such previously provided paired measured data. Accordingly, the step of generating the paired measured data may be omitted.

In some embodiments, the method comprises train a network (such as a cycleGAN or a network using patch-wise contrastive loss and a discriminator) in order to learn how to map AEI data from MEM data (i.e. the paired measured data that have undergone inspection after development) to AEI data that have not been damaged during ADI (e.g. hypothetical data simulating the sample after the etching process if the sample had not previously been measured before the etching process).

Alternatively, such a network may have previously been trained. A trained network may be provided and used for performing the mapping. The training step may be omitted.

In some embodiments, the method comprises applying the trained model on new MEM data. The output (i.e. the hypothetical data) may be used for relevant studies. For example, the output may be used to monitor whether there is any variation (e.g. drift) over time of the etching process. The output may be used to monitor one or more other aspects of the etching process, for example any defects.

The embodiments of the present disclosure may be embodied as a training scheme for using MEM experiment data while reducing/avoiding the effects of the ADI damage to the AEI data. At least some embodiments of the present disclosure are expected to produce hypothetical data that is closer to reality (i.e. closer to a pattern that did not undergo ADI) than the actual pattern inspected during a MEM experiment is to reality.

In some embodiments, the method comprises using the generator model to generate the hypothetical data based on the paired measured data. The paired measured data can be used to form an image of the sample, i.e. an AEI image. The hypothetical data can be used to form an image of the sample, i.e. a hypothetical AEI image. It is not necessary to actually generate the images. In some embodiments, the data may remain in non-image form. Alternatively, the images may be generated and displayed.

In some embodiments, the method comprises using a discriminator to evaluate a likelihood that the hypothetical data comes from a same data distribution as real measured data measured from a sample after an etching process, the sample not having previously been measured before the etching process.

In some embodiments, the method comprises producing the real measured data. The real measured data can be used to form an image of the sample, i.e. an AEI image (or multiple images of one or more locations of the sample). Alternatively the real measured data may have previously been produced. The step of producing the real measured data may be omitted.

In some embodiments, the real measured data corresponds to one or more locations of the sample that are physically similar (e.g. have similar features to) the location corresponding to the paired measured data. For example, if the paired measured data can be used to form an image of a contact hole, then desirably the real measured data corresponds to a location that has a contact hole similarly located.

In some embodiments, the real measured data corresponds to one or more locations of the sample that are located close to the location corresponding to the paired measured data. For example, desirably the real measured data corresponds to a location that neighbors the location corresponding to the paired measured data. This can help to account for any systematic variations of data measured at different positions of the sample (which may be referred to as the fingerprint). For example, it may be that there is a systematic effect related to the distance of the location from the center of the sample. In some embodiments, the real measured data corresponds to one or more locations that are a similar distance from the center of a sample as the paired measured data.

In some embodiments, the real measured data corresponds to one or more locations of the sample that have surrounding pattern density similar to the location corresponding to the paired measured data. For example, the location of the paired measured data may be surrounded by contact holes in a regular hexagonal pattern. Desirably the real measured data similarly corresponds to one or more locations of a sample that are surrounded by regularly spaced contact holes.

In some embodiments, the method comprises training the generator model based on the likelihood evaluated by the discriminator. In some embodiments, the generator model is trained so as to increase the likelihood evaluated by the discriminator. This helps to increase the closeness between the hypothetical data that is produced and what data would have been measured had the sample location not undergone ADI.

As mentioned above, in some embodiments, contrastive loss may be used. In some embodiments, the method comprises training the generator model based on a function indicative of a level of correlation between the paired measured data and the hypothetical data. In some embodiments, the method comprises pairing subsets of the paired measured data with subsets of the hypothetical data, the subsets corresponding to locations within the images of the sample that can be formed from the paired measured data and the hypothetical data. The function (which is indicative of a level of correlation between the paired measured data and the hypothetical data) is correlation for the pairs corresponding to a same location relative to correlation for pairs corresponding to different locations, the correlation being the correlation between the paired subsets of data.

In some embodiments, the generator model is trained so as to increase correlation for the pairs corresponding to a same location relative to correlation for pairs corresponding to different locations. In some embodiments, the method comprises determining cross-entropy of extracted features of the paired subsets of data so as to determine the correlation between the paired subsets of data. In some embodiments, the method comprises encoding the paired subsets of data with an encoder of the generator model such that the features can be extracted.

Alternatively, as mentioned above in some embodiments, a cycleGAN may be used. In some embodiments, the method comprises using a backward generator model to generate simulated paired data based on the hypothetical data, wherein the simulated paired data can be used to form an image of the sample. The function (which is indicative of a level of correlation between the paired measured data and the hypothetical data) is similarity between the paired measured data and the simulated paired data. In some embodiments, the generator model and the backward generator model are trained so as to increase the similarity between the paired measured data and the simulated paired data.

In some embodiments, a processor apparatus is provided comprising a processor configured to perform the method described above. For example, a processor may be configured to perform the method of training the generator model. Additionally or alternatively, the processor may be configured to perform the method of applying the generator model.

In some embodiments, an assessment method is provided that comprises generating a sample map according to any of the methods described above. The assessment method comprises inspecting the sample 208 using the generated sample map to locate one or more features of interest. The assessment method may comprise assessing the extent to which the one or more features of interest contain defects. This may be achieved by comparing images of the features of interest with reference images elsewhere on the sample, on other samples, or in a database.

In some embodiments, the inspection is performed by directing one or more beams of charged particles (e.g., electrons) onto the sample 208 and detecting one or more charged particles (e.g., electrons) emitted from the sample 208. The inspection may use any of the electron-optical arrangements described above with reference to FIG. 1-5 or any other suitable arrangement for inspecting a sample using a beam of charged particles. The inspection may also be performed using other techniques, such as optical techniques based on electromagnetic radiation.

References to upper and lower, up and down, above and below, etc. should be understood as referring to directions parallel to the (typically but not always vertical) up-beam and down-beam directions of the electron beam or multi-beam impinging on the sample 208. Thus, references to up beam and down beam are intended to refer to directions in respect of the beam path independently of any present gravitational field.

The embodiments herein described may take the form of a series of aperture arrays or electron-optical elements arranged in arrays along a beam or a multi-beam path. Such electron-optical elements may be electrostatic. In some embodiments, all the electron-optical elements, for example from a beam limiting aperture array to a last electron-optical element in a sub-beam path before a sample, may be electrostatic and/or may be in the form of an aperture array or a plate array. In some arrangements one or more of the electron-optical elements are manufactured as a microelectromechanical system (MEMS) (i.e. using MEMS manufacturing techniques). Electron-optical elements may have magnetic elements and electrostatic elements. For example, a compound array lens may feature a macro magnetic lens encompassing the multi-beam path with an upper and lower pole plate within the magnetic lens and arranged along the multi-beam path. In the pole plates may be an array of apertures for the beam paths of the multi-beam. Electrodes may be present above, below or between the pole plates to control and optimize the electro-magnetic field of the compound lens array.

An assessment tool or assessment system according to the disclosure may comprise apparatus which makes a qualitative assessment of a sample (e.g. pass/fail), one which makes a quantitative measurement (e.g. the size of a feature) of a sample or one which generates an image of map of a sample. Examples of assessment tools or systems are inspection tools (e.g. for identifying defects), review tools (e.g. for classifying defects) and metrology tools, or tools capable of performing any combination of assessment functionalities associated with inspection tools, review tools, or metrology tools (e.g. metro-inspection tools).

Reference to a component or system of components or elements being controllable to manipulate a charged particle beam in a certain manner includes configuring a controller or control system or control unit to control the component to manipulate the charged particle beam in the manner described, as well optionally using other controllers or devices (e.g. voltage supplies) to control the component to manipulate the charged particle beam in this manner. For example, a voltage supply may be electrically connected to one or more components to apply potentials to the components, such as to the electrodes of the control lens array 250 and objective lens array 241, under the control of the controller or control system or control unit. An actuatable component, such as a stage, may be controllable to actuate and thus move relative to another components such as the beam path using one or more controllers, control systems, or control units to control the actuation of the component.

Functionality provided by the controller or control system or control unit may be computer-implemented. Any suitable combination of elements may be used to provide the required functionality, including for example CPUs, RAM, SSDs, motherboards, network connections, firmware, software, and/or other elements known in the art that allow the required computing operations to be performed. The required computing operations may be defined by one or more computer programs. The one or more computer programs may be provided in the form of media, optionally non-transitory media, storing computer readable instructions. When the computer readable instructions are read by the computer, the computer performs the required method steps. The computer may consist of a self-contained unit or a distributed computing system having plural different computers connected to each other via a network.

The terms “sub-beam” and “beamlet” are used interchangeably herein and are both understood to encompass any radiation beam derived from a parent radiation beam by dividing or splitting the parent radiation beam. The term “manipulator” is used to encompass any element which affects the path of a sub-beam or beamlet, such as a lens or deflector. References to elements being aligned along a beam path or sub-beam path are understood to mean that the respective elements are positioned along the beam path or sub-beam path. References to optics are understood to mean electron-optics.

The methods of the various embodiments may be performed by computer systems comprising one or more computers. A computer used to implement the various embodiments may comprise one or more processors, including general purpose CPUs, graphical processing units (GPUs), Field Programmable Gate Arrays (FPGAs), Application Specific Integrated Circuits (ASICs) or other specialized processors. As discussed above, in some cases specific types of processor may provide advantages in terms of reduced cost and/or increased processing speed and the method of the various embodiments may be adapted to the use of specific processor types. Certain steps of methods of the various embodiments may involve parallel computations that are apt to be implemented on processers capable of parallel computation, for example GPUs.

The term “image” used herein is intended to refer to any array of values wherein each value relates to a sample of a location and the arrangement of values in the array corresponds to a spatial arrangement of the sampled locations. An image may comprise a single layer or multiple layers. In the case of a multi-layer image, each layer, which may also be referred to as a channel, represents a different sample of the locations. The term “pixel” is intended to refer to a single value of the array or, in the case of a multi-layer image, a group of values corresponding to a single location.

Embodiments of the disclosure are defined in the following numbered clauses.

1. A method of training a generator model that processes first measured data measured from a sample before an etching process to generate predictive data predicting the sample after an etching process, the method comprising:
using the generator model to generate the predictive data based on the first measured data, wherein the first measured data and the predictive data can be used to form images of the sample;
pairing subsets of the first measured data with subsets of the predictive data, the subsets corresponding to locations within the images of the sample that can be formed from the measured data and the predictive data;
using a discriminator to evaluate a likelihood that the predictive data comes from a same data distribution as second measured data measured from a sample at a different location after an etching process; and
training the generator model based on:
correlation for the pairs corresponding to a same location relative to correlation for pairs corresponding to different locations, the correlation being the correlation between the paired subsets of data, and
the likelihood evaluated by the discriminator.
   2. The method of clause 1, wherein the generator model is trained so as to increase correlation for the pairs corresponding to a same location relative to correlation for pairs corresponding to different locations.
   3. The method of clause 1 or 2, wherein the generator model is trained so as to increase the likelihood evaluated by the discriminator.
   4. The method of any preceding clause, comprising:
calculating one or more parameter values for one or more parameters of features of the sample from the predictive data and from the second measured data; and
comparing the one or more parameter values calculated from the predictive data to the one or more parameter values calculated from the second measured data,
wherein the evaluation by the discriminator is dependent on the comparison of the one or more parameter values.
   5. The method of clause 4, wherein the parameters comprise one or more of critical dimension, local critical dimension uniformity, local edge placement error, line edge roughness and line width roughness.
   6. The method of clause 4 or 5, wherein the likelihood evaluated by the discriminator is greater for a smaller difference between the one or more parameter values calculated from the predictive data and the one or more parameter values calculated from the second measured data.
   7. The method of any preceding clause, wherein the second measured data correspond to a different location from the first measured data.
   8. The method of any preceding clause, wherein mapping between the first measured data and the second measured data is non-invertible.
   9. The method of any preceding clause, wherein the generator model comprises an encoder and a decoder.
   10. The method of clause 9, comprising determining cross-entropy of extracted features of the paired subsets of data so as to determine the correlation between the paired subsets of data.
   11. The method of clause 10, comprising encoding the paired subsets of data with the encoder such that the features can be extracted.
   12. The method of any preceding clause, wherein the first measured data is measured from the sample before an etching process and after a lithographic exposure process.
   13. A method of processing first measured data measured from a sample before an etching process to generate predictive data predicting the sample after an etching process, the method comprising:
using a generator model to generate the predictive data based on the first measured data, wherein the generator model has been trained by the method of any preceding clause.
   14. A processing apparatus comprising:
a processor configured to perform the method of any preceding clause.
   15. A computer program comprising instructions configured to control a processor to perform the method of any preceding clause.
   16. A generator model training apparatus for training a generator model that processes first measured data measured from a sample before an etching process to generate predictive data predicting the sample after an etching process, the apparatus comprising:
a processor configured to:
   use the generator model to generate the predictive data based on the first measured data, wherein the first measured data and the predictive data can be used to form images of the sample;
   pair subsets of the first measured data with subsets of the predictive data, the subsets corresponding to locations within the images of the sample that can be formed from the first measured data and the predictive data;
   use a discriminator to evaluate a likelihood that the predictive data comes from a same data distribution as second measured data measured from a sample at a different location after an etching process; and
   train the generator model based on:
      correlation for the pairs corresponding to a same location relative to correlation for pairs corresponding to different locations, the correlation being the correlation between the paired subsets of data, and
      the likelihood evaluated by the discriminator.
         17. The generator model training apparatus of clause 16, wherein the processor is configured to train the generator model so as to increase correlation for the pairs corresponding to a same location relative to correlation for pairs corresponding to different locations.
         18. The generator model training apparatus of clause 16 or 17, wherein the processor is configured to train the generator model so as to increase the likelihood evaluated by the discriminator.
         19. The generator model training apparatus of any of clauses 16-18, wherein the processor is configured to:
calculate one or more parameter values for one or more parameters of features of the sample from the predictive data and from the second measured data; and
compare the one or more parameter values calculated from the predictive data to the one or more parameter values calculated from the second measured data,
wherein the evaluation by the discriminator is dependent on the comparison of the one or more parameter values.
   20. The generator model training apparatus of clause 19, wherein the parameters comprise one or more of critical dimension, local critical dimension uniformity, local edge placement error, line edge roughness and line width roughness.
   21. The generator model training apparatus of clause 19 or 20, wherein the likelihood evaluated by the discriminator is greater for a smaller difference between the one or more parameter values calculated from the predictive data and the one or more parameter values calculated from the second measured data.
   22. The generator model training apparatus of any of clauses 16-21, wherein the second measured data correspond to a different location from the first measured data.
   23. The generator model training apparatus of any of clauses 16-22, wherein mapping between the first measured data and the second measured data is non-invertible.
   24. The generator model training apparatus of any of clauses 16-23, wherein the generator model comprises an encoder and a decoder.
   25. The generator model training apparatus of clause 24, wherein the processor is configured to determine cross-entropy of extracted features of the paired subsets of data so as to determine the correlation between the paired subsets of data.
   26. The generator model training apparatus of clause 25, wherein the processor is configured to encode the paired subsets of data with the encoder such that the features can be extracted.
   27. The generator model training apparatus of any of clauses 16-26, wherein the first measured data is measured from the sample before an etching process and after a lithographic exposure process.
   28. A predictive data generating apparatus for processing first measured data measured from a sample before an etching process to generate predictive data predicting the sample after an etching process, the apparatus comprising:
a processor configured to:
   use a generator model to generate the predictive data based on the first measured data, wherein the generator model has been trained by the method of any of clauses 1-12.
      29. A computer readable medium storing instructions configured to control a processor to train a generator model that processes first measured data measured from a sample before an etching process to generate predictive data predicting the sample after an etching process, the computer readable medium storing instructions configured to control the processor to:
use the generator model to generate the predictive data based on the first measured data, wherein the first measured data and the predictive data can be used to form images of the sample;
pair subsets of the first measured data with subsets of the predictive data, the subsets corresponding to locations within the images of the sample that can be formed from the measured data and the predictive data;
use a discriminator to evaluate a likelihood that the predictive data comes from a same data distribution as second measured data measured from a sample at a different location after an etching process; and
train the generator model based on:
   correlation for the pairs corresponding to a same location relative to correlation for pairs corresponding to different locations, the correlation being the correlation between the paired subsets of data, and
   the likelihood evaluated by the discriminator.
      30. The computer readable medium of clause 29, storing instructions configured to control the processor to train the generator model so as to increase correlation for the pairs corresponding to a same location relative to correlation for pairs corresponding to different locations.
      31. The computer readable medium of clause 29 or 30, storing instructions configured to control the processor to train the generator model so as to increase the likelihood evaluated by the discriminator.
      32. The computer readable medium of any of clauses 29-31, storing instructions configured to control the processor to:
calculate one or more parameter values for one or more parameters of features of the sample from the predictive data and from the second measured data; and
compare the one or more parameter values calculated from the predictive data to the one or more parameter values calculated from the second measured data,
wherein the evaluation by the discriminator is dependent on the comparison of the one or more parameter values.
   33. The computer readable medium of clause 32, wherein the parameters comprise one or more of critical dimension, local critical dimension uniformity, local edge placement error, line edge roughness and line width roughness.
   34. The computer readable medium of clause 32 or 33, wherein the likelihood evaluated by the discriminator is greater for a smaller difference between the one or more parameter values calculated from the predictive data and the one or more parameter values calculated from the second measured data.
   35. The computer readable medium of any of clauses 29-34, wherein the second measured data correspond to a different location from the first measured data.
   36. The computer readable medium of any of clauses 29-35, wherein mapping between the first measured data and the second measured data is non-invertible.
   37. The computer readable medium of any of clauses 29-36, wherein the generator model comprises an encoder and a decoder.
   38. The computer readable medium of clause 37, storing instructions configured to control the processor to determine cross-entropy of extracted features of the paired subsets of data so as to determine the correlation between the paired subsets of data.
   39. The computer readable medium of clause 38, storing instructions configured to control the processor to encode the paired subsets of data with the encoder such that the features can be extracted.
   40. The computer readable medium of any of clauses 29-39, wherein the first measured data is measured from the sample before an etching process and after a lithographic exposure process.
   41. A method of training a generator model that processes paired measured data measured from a sample after an etching process, the sample having previously been measured before the etching process, to generate hypothetical data simulating the sample after the etching process if the sample had not previously been measured before the etching process, the method comprising:
using the generator model to generate the hypothetical data based on the paired measured data, wherein the paired measured data and the hypothetical data can be used to form images of the sample;
using a discriminator to evaluate a likelihood that the hypothetical data comes from a same data distribution as real measured data measured from a sample after an etching process, the sample not having previously been measured before the etching process; and
training the generator model based on:
   a function indicative of a level of correlation between the paired measured data and the hypothetical data, and
   the likelihood evaluated by the discriminator.
      42. The method of clause 41, comprising:
pairing subsets of the paired measured data with subsets of the hypothetical data, the subsets corresponding to locations within the images of the sample that can be formed from the paired measured data and the hypothetical data;
wherein the function is correlation for the pairs corresponding to a same location relative to correlation for pairs corresponding to different locations, the correlation being the correlation between the paired subsets of data.
   43. The method of clause 42, wherein the generator model is trained so as to increase correlation for the pairs corresponding to a same location relative to correlation for pairs corresponding to different locations.
   44. The method of clause 42 or 43, comprising determining cross-entropy of extracted features of the paired subsets of data so as to determine the correlation between the paired subsets of data.
   45. The method of clause 44, comprising encoding the paired subsets of data with an encoder of the generator model such that the features can be extracted.
   46. The method of clause 41, comprising:
using a backward generator model to generate simulated paired data based on the hypothetical data, wherein the simulated paired data can be used to form an image of the sample;
wherein the function is similarity between the paired measured data and the simulated paired data.
   47. The method of clause 46, wherein the generator model and the backward generator model are trained so as to increase the similarity between the paired measured data and the simulated paired data.
   48. The method of any of clauses 41-47, wherein the generator model is trained so as to increase the likelihood evaluated by the discriminator.
   49. The method of any of clauses 41-48, wherein the paired measured data is measured from a sample after an etching process, the sample having previously been measured before the etching process and after a lithographic exposure process.
   50. A method of processing paired measured data measured from a sample after an etching process, the sample having previously been measured before the etching process, to generate hypothetical data simulating the sample after the etching process if the sample had not previously been measured before the etching process, the method comprising:
using a generator model to generate the hypothetical data based on the paired measured data, wherein the generator model has been trained by the method of any of clauses 41-49.
   51. A processing apparatus comprising:
a processor configured to perform the method of any of clauses 41-50.
   52. A computer program comprising instructions configured to control a processor to perform the method of any of clauses 41-51.
   53. A generator model training apparatus for training a generator model that processes paired measured data measured from a sample after an etching process, the sample having previously been measured before the etching process, to generate hypothetical data simulating the sample after the etching process if the sample had not previously been measured before the etching process, the apparatus comprising:
a processor configured to:
   use the generator model to generate the hypothetical data based on the paired measured data, wherein the paired measured data and the hypothetical data can be used to form images of the sample;
   use a discriminator to evaluate a likelihood that the hypothetical data comes from a same data distribution as real measured data measured from a sample after an etching process, the sample not having previously been measured before the etching process; and
   train the generator model based on:
      a function indicative of a level of correlation between the paired measured data and the hypothetical data, and
      the likelihood evaluated by the discriminator.
         54. The generator model training apparatus of clause 53, wherein the processor is configured to:
pair subsets of the paired measured data with subsets of the hypothetical data, the subsets corresponding to locations within the images of the sample that can be formed from the paired measured data and the hypothetical data;
wherein the function is correlation for the pairs corresponding to a same location relative to correlation for pairs corresponding to different locations, the correlation being the correlation between the paired subsets of data.
   55. The generator model training apparatus of clause 54, wherein the processor is configured to train the generator model so as to increase correlation for the pairs corresponding to a same location relative to correlation for pairs corresponding to different locations.
   56. The generator model training apparatus of clause 54 or 55, wherein the processor is configured to determine cross-entropy of extracted features of the paired subsets of data so as to determine the correlation between the paired subsets of data.
   57. The generator model training apparatus of clause 56, wherein the processor is configured to encode the paired subsets of data with an encoder of the generator model such that the features can be extracted.
   58. The generator model training apparatus of clause 53, wherein the processor is configured to:
use a backward generator model to generate simulated paired data based on the hypothetical data, wherein the simulated paired data can be used to form an image of the sample;
wherein the function is similarity between the paired measured data and the simulated paired data.
   59. The generator model training apparatus of clause 58, wherein the generator model and the backward generator model are trained so as to increase the similarity between the paired measured data and the simulated paired data.
   60. The generator model training apparatus of any of clauses 53-59, wherein the processor is configured to train the generator model so as to increase the likelihood evaluated by the discriminator.
   61. The generator model training apparatus of any of clauses 53-60, wherein the paired measured data is measured from a sample after an etching process, the sample having previously been measured before the etching process and after a lithographic exposure process.
   62. A hypothetical data generating apparatus for processing paired measured data measured from a sample after an etching process, the sample having previously been measured before the etching process, to generate hypothetical data simulating the sample after the etching process if the sample had not previously been measured before the etching process, the apparatus comprising:
a processor configured to:
   use a generator model to generate the hypothetical data based on the paired measured data, wherein the generator model has been trained by the method of any of clauses 41-49.
      63. A computer readable medium storing instructions configured to control a processor to train a generator model that processes paired measured data measured from a sample after an etching process, the sample having previously been measured before the etching process, to generate hypothetical data simulating the sample after the etching process if the sample had not previously been measured before the etching process, the computer readable medium storing instructions configured to control the processor to:
use the generator model to generate the hypothetical data based on the paired measured data, wherein the paired measured data and the hypothetical data can be used to form images of the sample;
use a discriminator to evaluate a likelihood that the hypothetical data comes from a same data distribution as real measured data measured from a sample after an etching process, the sample not having previously been measured before the etching process; and
train the generator model based on:
   a function indicative of a level of correlation between the paired measured data and the hypothetical data, and
      the likelihood evaluated by the discriminator.
         64. The computer readable medium of clause 63, storing instructions configured to control the processor to pair subsets of the paired measured data with subsets of the hypothetical data, the subsets corresponding to locations within the images of the sample that can be formed from the paired measured data and the hypothetical data;
wherein the function is correlation for the pairs corresponding to a same location relative to correlation for pairs corresponding to different locations, the correlation being the correlation between the paired subsets of data.
   65. The computer readable medium of clause 64, storing instructions configured to control the processor to train the generator model so as to increase correlation for the pairs corresponding to a same location relative to correlation for pairs corresponding to different locations.
   66. The computer readable medium of clause 64 or 65, storing instructions configured to control the processor to determine cross-entropy of extracted features of the paired subsets of data so as to determine the correlation between the paired subsets of data.
   67. The computer readable medium of clause 66, storing instructions configured to control the processor to encode the paired subsets of data with an encoder of the generator model such that the features can be extracted.
   68. The computer readable medium of clause 63, storing instructions configured to control the processor to use a backward generator model to generate simulated paired data based on the hypothetical data, wherein the simulated paired data can be used to form an image of the sample;
wherein the function is similarity between the paired measured data and the simulated paired data.
   69. The computer readable medium of clause 68, wherein the generator model and the backward generator model are trained so as to increase the similarity between the paired measured data and the simulated paired data.
   70. The computer readable medium of any of clauses 63-69, storing instructions configured to control the processor to train the generator model so as to increase the likelihood evaluated by the discriminator.
   71. The computer readable medium of any of clauses 63-70, wherein the paired measured data is measured from a sample after an etching process, the sample having previously been measured before the etching process and after a lithographic exposure process.

A computer used to implement the various embodiments may be physical or virtual. A computer used to implement the various embodiments may be a server, a client or a workstation. Multiple computers used to implement the various embodiments may be distributed and interconnected via a local area network (LAN) or wide area network (WAN). Results of a method of the various embodiments may be displayed to a user or stored in any suitable storage medium. The embodiments of the present disclosure may be embodied in a non-transitory computer-readable storage medium storing instructions to carry out the disclosed methods. The embodiments of the present disclosure may be embodied in computer system comprising one or more processors and memory or storage storing instructions to carry out the disclosed methods.

While the present invention has been described in connection with various embodiments, other embodiments of the invention will be apparent to those skilled in the art from consideration of the specification and practice of the technology disclosed herein. It is intended that the specification and examples be considered as exemplary only, with a true scope and spirit of the invention being indicated by the clauses and the following claims.

1. A method of training a generator model that processes first measured data measured from a sample before an etching process to generate predictive data predicting the sample after an etching process, the method comprising:
using the generator model to generate the predictive data based on the first measured data, wherein the first measured data and the predictive data can be used to form images of the sample;
pairing subsets of the first measured data with subsets of the predictive data, the subsets corresponding to locations within the images of the sample that can be formed from the measured data and the predictive data;
using a discriminator to evaluate a likelihood that the predictive data comes from a same data distribution as second measured data measured from a sample at a different location after an etching process; and
training the generator model based on:
correlation for the pairs corresponding to a same location relative to correlation for pairs corresponding to different locations, the correlation being the correlation between the paired subsets of data, and
the likelihood evaluated by the discriminator.

2. The method of claim 1, wherein the generator model is trained so as to increase correlation for the pairs corresponding to a same location relative to correlation for pairs corresponding to different locations.

3. The method of claim 1, wherein the generator model is trained so as to increase the likelihood evaluated by the discriminator.

4. The method of claim 1, further comprising:
calculating one or more parameter values for one or more parameters of features of the sample from the predictive data and from the second measured data; and
comparing the one or more parameter values calculated from the predictive data to the one or more parameter values calculated from the second measured data,
wherein the evaluation by the discriminator is dependent on the comparison of the one or more parameter values.

5. The method of claim 4, wherein the parameters comprise one or more of critical dimension, local critical dimension uniformity, local edge placement error, line edge roughness and line width roughness.

6. The method of claim 4, wherein the likelihood evaluated by the discriminator is greater for a smaller difference between the one or more parameter values calculated from the predictive data and the one or more parameter values calculated from the second measured data.

7. The method of claim 1, wherein the second measured data correspond to a different location from the first measured data.

8. The method of claim 1, wherein mapping between the first measured data and the second measured data is non-invertible.

9. The method of claim 1, wherein the generator model comprises an encoder and a decoder.

10. The method of claim 9, further comprising determining cross-entropy of extracted features of the paired subsets of data so as to determine the correlation between the paired subsets of data.

11. The method of claim 10, further comprising encoding the paired subsets of data with the encoder such that the features can be extracted.

12. The method of claim 1, wherein the first measured data is measured from the sample before an etching process and after a lithographic exposure process.

13. A processing apparatus comprising:
one or more processors configured to perform operations for training a generator model that processes first measured data measured from a sample before an etching process to generate predictive data predicting the sample after an etching process, the operations comprising:
using the generator model to generate the predictive data based on the first measured data, wherein the first measured data and the predictive data can be used to form images of the sample;
pairing subsets of the first measured data with subsets of the predictive data, the subsets corresponding to locations within the images of the sample that can be formed from the measured data and the predictive data;
using a discriminator to evaluate a likelihood that the predictive data comes from a same data distribution as second measured data measured from a sample at a different location after an etching process; and
training the generator model based on:
correlation for the pairs corresponding to a same location relative to correlation for pairs corresponding to different locations, the correlation being the correlation between the paired subsets of data, and
the likelihood evaluated by the discriminator.

14. The processing apparatus of claim 13, wherein the generator model is trained so as to increase correlation for the pairs corresponding to a same location relative to correlation for pairs corresponding to different locations.

15. The processing apparatus of claim 13, wherein the generator model is trained so as to increase the likelihood evaluated by the discriminator.

16. The processing apparatus of claim 13, wherein the operations further comprise:
calculating one or more parameter values for one or more parameters of features of the sample from the predictive data and from the second measured data; and
comparing the one or more parameter values calculated from the predictive data to the one or more parameter values calculated from the second measured data,
wherein the evaluation by the discriminator is dependent on the comparison of the one or more parameter values.

17. The processing apparatus of claim 16, wherein the parameters comprise one or more of critical dimension, local critical dimension uniformity, local edge placement error, line edge roughness and line width roughness.

18. The processing apparatus of claim 16, wherein the likelihood evaluated by the discriminator is greater for a smaller difference between the one or more parameter values calculated from the predictive data and the one or more parameter values calculated from the second measured data.

19. The processing apparatus of claim 13, wherein the second measured data correspond to a different location from the first measured data.

20. A computer program comprising instructions configured to control one or more processors to cause a system to perform operations for processing first measured data measured from a sample before an etching process to generate predictive data predicting the sample after an etching process, the operations comprising:
using a generator model to generate the predictive data based on the first measured data. wherein the generator model has been trained according to the method of claim 1.
